(19) United States
(12) Patent Application Publication
(10) Pub. No.: US 2019/0198822 A1
(43) Pub. Date: Jun. 27, 2019

(54) FLEXIBLE SUBSTRATE OF FLEXIBLE OLED DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Bin XU, Wuhan, Hubei (CN)

(21) Appl. No.: 15/579,884

(22) PCT Filed: Nov. 2, 2017
(86) PCT No.: PCT/CN2017/109090

§ 371 Date: Dec. 3, 2018

(30) Foreign Application Priority Data
Aug. 18, 2017 (CN) 201710714005.4

(51) Int. Cl. H01L 51/56; H01L 51/00; H01L 51/52

(52) U.S. Cl. CPC H01L 51/56; H01L 51/0097; H01L 2251/5338; H01L 51/5253; H01L 51/0001

(57) ABSTRACT

The present invention provides a manufacturing method of a flexible substrate of an OLED display panel including a step S10 of providing a first polyimide layer; a step S20 of forming a first silicon oxide layer on a surface of the first polyimide layer; a step S30 of forming a second silicon oxide layer on a surface of the first silicon oxide layer; a step S40 of forming an amorphous silicon layer on a surface of the second silicon oxide layer; and a step S50 of forming a second polyimide layer on a surface of the amorphous silicon layer.

### CROSS REFERENCE TO RELATED APPLICATIONS

This application is a U.S. National Phase application submitted under 35 U.S.C. § 371 of Patent Cooperation Treaty Application serial No. PCT/CN2017/109090, filed on Nov. 02, 2017, which claims the priority of China Patent Application serial No. 201710714005.4, filed on Aug. 18, 2017, the disclosures of which are incorporated herein by reference in their entirety.

### FIELD OF INVENTION

The present invention relates to field of display technologies, and more particularly to a flexible substrate of a flexible OLED display panel and a manufacturing method thereof.

### BACKGROUND OF INVENTION

Organic light-emitting diode (OLED) displays, also known as organic electroluminescent displays, are a new type of flat panel display device. OLED displays have advantages such as simple production processes, low production costs, low power consumption, high luminous brightness, wide operating temperature range, thin volume, fast response times, easy color display and large screen display, easy matching with integrated circuit drivers, easy flexible display, etc. As a result, OLED displays have broad application prospects. Nowadays, the flexible OLED panels have become an important research direction for organic light-emitting devices. Flexible substrates are selected to replace conventional glass substrate to achieve the flexibility of panels.

In conventional flexible substrates, in a film layer structure, typically upper and lower polyimide (PI) layers are included, a silicon oxide layer, and a silicon nitride layer, etc., disposed between the two PI layers. Because materials of the silicon oxide and silicon nitride are different, manufacturing process requires different material deposition apparatuses, which results in more complicated processes and low efficiency of production.

### SUMMARY OF INVENTION

The present invention provides a manufacturing method of a flexible substrate of an OLED display panel that can reduce the manufacturing processes of the flexible substrate and improve the production efficiency. The present invention also can solve the technological problems as follows: in the film layers of the conventional flexible substrate, since materials of the silicon oxide and silicon nitride are different, the manufacturing process needs to pass different material deposition apparatus, which results in the processes being more complicated and the efficiency of production being low.

In order to solve the above-mentioned problems, the technical solutions provided by the present invention are as follows:

The present invention provides a manufacturing method of a flexible substrate of an OLED display panel, comprising:

a step S10 of providing a first polyimide layer;

a step S20 of forming a first silicon oxide layer on a surface of the first polyimide layer;

a step S30 of forming a second silicon oxide layer on a surface of the first silicon oxide layer;

a step S40 of forming an amorphous silicon layer on a surface of the second silicon oxide layer; and

a step S50 of forming a second polyimide layer on a surface of the amorphous silicon layer;

wherein the step S10 further comprises:

a step S101 of forming a recess array on a side of the first polyimide layer which is away from the first silicon oxide layer.

According to a preferred embodiment of the present invention, in the step S20 and the step S30, the first silicon oxide layer and the second silicon oxide layer are sequentially formed in the same chemical vapor deposition chamber, and wherein a material deposition time of the first silicon oxide layer is less than a material deposition time of the second silicon oxide layer.

According to a preferred embodiment of the present invention, in the step S30, the second silicon oxide layer is deposited on the surface of the first oxide layer by using a chemical vapor deposition apparatus having a power ranging from 300 W to 700 W.

According to a preferred embodiment of the present invention, a film thickness of the second silicon oxide layer is about 800 to 1100 angstroms.

According to a preferred embodiment of the present invention, the film thickness of the second silicon oxide layer is about a quarter of a film thickness of the first silicon oxide layer.

The present invention further provides a manufacturing method of a flexible substrate of an OLED display panel, comprising:

a step S10 of providing a first polyimide layer;

a step S20 of forming a first silicon oxide layer on a surface of the first polyimide layer;

a step S30 of forming a second silicon oxide layer on a surface of the first silicon oxide layer;

a step S40 of forming an amorphous silicon layer on a surface of the second silicon oxide layer; and a step S50 of forming a second polyimide layer on a surface of the amorphous silicon layer.

According to a preferred embodiment of the present invention, in the step S20 and the step S30, the first silicon oxide layer and the second silicon oxide layer are sequentially formed in the same chemical vapor deposition chamber, and wherein a material deposition time of the first silicon oxide layer is less than a material deposition time of the second silicon oxide layer.

According to a preferred embodiment of the present invention, in the step S30, the second silicon oxide layer is deposited on the surface of the first oxide layer by using a chemical vapor deposition apparatus having a power ranging from 300 W to 700 W.

According to a preferred embodiment of the present invention, a film thickness of the second silicon oxide layer is about 800 to 1100 angstroms.

According to a preferred embodiment of the present invention, the film thickness of the second silicon oxide layer is about a quarter of a film thickness of the first silicon oxide layer.

According to the above object of the present invention, the present invention provides a flexible substrate manufactured by a manufacturing method of a flexible substrate of an OLED display panel, comprising:

a first polyimide layer;

a first silicon oxide layer disposed on a surface of the first polyimide layer;

a second silicon oxide layer disposed on a surface of the first silicon oxide layer;

an amorphous silicon layer disposed on a surface of the second silicon oxide layer; and

a second polyimide layer disposed on a surface of the amorphous silicon layer.

According to a preferred embodiment of the present invention, a film thickness of the second silicon oxide layer is about 800 to 1100 angstroms.

According to a preferred embodiment of the present invention, the film thickness of the second silicon oxide layer is about a quarter of a film thickness of the first silicon oxide layer.

According to a preferred embodiment of the present invention, a film consistency of the second silicon oxide layer is greater than a film consistency of the first silicon oxide layer

According to a preferred embodiment of the present invention, a plurality of recesses arranged in an array arrangement are formed on a surface of the first polyimide layer and a surface of the second polyimide layer.

The present invention has the advantages: in comparison with the prior art, the flexible substrate according to the present invention provides the manufacturing processes being relatively simplified such that improves the production efficiency of the flexible substrate. In comparison with the film layers of the conventional flexible substrate, the present invention also can solve the technology problems as follows: since materials of the silicon oxide and silicon nitride are different, the manufacturing process need to pass different material deposition apparatus, which result in the processes are more complicated and the efficiency of production is low.

### DESCRIPTION OF DRAWINGS

In order to more clearly illustrate the technical solutions in the embodiments or the prior art, the following drawings, which are intended to be used in the description of the embodiments or the prior art, will be briefly described. It will be apparent that the drawings and the following description are only some embodiments of the present invention. Those of ordinary skill in the art may, without creative efforts, derive other drawings from these drawings.

FIG. 1 illustrates a process flow of a manufacturing method of a flexible substrate of an OLED display panel according the present invention.

FIG. 2 illustrates a schematic view of a flexible substrate structure provided according to the present invention.

### DETAILED DESCRIPTION OF PREFERRED EMBODIMENTS

The structure and the technical means adopted by the present invention to achieve the above and other objects may be best understood by referring to the following detailed description of the preferred embodiments and the accompanying drawings. Furthermore, directional terms described by the present invention, such as upper, lower, front, back, left, right, inner, outer, side, longitudinal/vertical, transverse/horizontal, etc., are only directions by referring to the accompanying drawings, and thus the used directional terms are used to describe and understand the present invention, but the present invention is not limited thereto.

The present invention is directed against thin layers of a conventional flexible substrate, the technological problems are as follows: since materials of the silicon oxide and silicon nitride are different, the manufacturing process needs to pass different material deposition apparatus, which results in the processes being more complicated and the efficiency of production being low. The present embodiment can solve the problems.

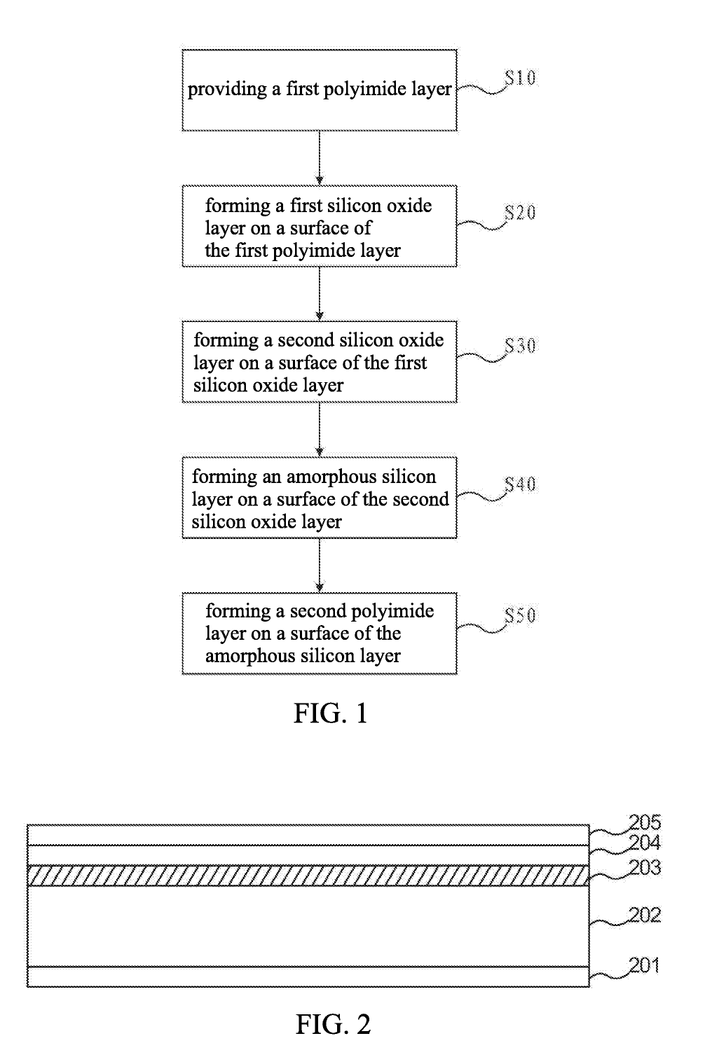

Referring to FIG. 1, an embodiment according to present invention provides a manufacturing method of a flexible substrate of an OLED display panel, includes steps:

In a step S10, a first polyimide layer is provided.

In a step S20, a first silicon oxide layer is formed on a surface of the first polyimide layer.

In a step S30, a second silicon oxide layer is formed on a surface of the first silicon oxide layer.

In a step S40, an amorphous silicon layer is formed on a surface of the second silicon oxide layer.

In a step S50, a second polyimide layer is formed on a surface of the amorphous silicon layer.

In the step S10 and the step 50, the first polyimide layer and the second polyimide layer have high bending performance and impact resistance, and are configured as an upper protective layer and a lower protective layer of a flexible substrate, a surface of the second polyimide layer is attached to an OLED display panel.

In an exemplary embodiment, the step S10 further comprises a step S101: forming a recess array on a side of the first polyimide layer which is away from the first silicon oxide layer. The recess array is configured to disperse a bending stress on a surface of the first polyimide layer such that prevent cracking of the first polyimide layer during the bending. Similarly, the step S50 further comprises a step S501: forming a recess array on a side of the first polyimide layer which is away from the amorphous silicon layer.

In the step S20, the first silicon oxide layer is formed on the surface of the first polyimide layer, a thickness of the first polyimide layer in the flexible substrate is thickest, which serves as a buffer for the flexible substrate during bending and prevents to cause film damage where the bending angle of the flexible substrate is excessively large during bending, the polyimide layer is used to protect other film.

The step S20 further comprises a step S201: the first silicon oxide layer is formed by using fast deposition (Fast Depo). Since the first silicon oxide layer is configured to be a buffer layer of the flexible substrate, the film layer is thicker, and does not require blocking moisture and oxygen erosion, Fast Depo relatively saves manufacturing time and forms less compact film layer, for example, the first silicon oxide layer is formed by a chemical vapor deposition apparatus having a power ranging from 2500 W to 3000 W, depositing the first oxide layer on the first polyimide layer.

In a step S30, the second silicon oxide layer is formed on the surface of the first silicon oxide layer. The second silicon oxide layer is configured to highly efficient of blocking oxygen and air. Therefore, the second silicon oxide layer needs to have a relatively high density and a thickness of the second silicon oxide layer is much smaller than a thickness of the first silicon oxide layer.

In the step S20 and the step S30, the first silicon oxide layer and the second silicon oxide layer are formed in the same chemical vapor deposition chamber, the second silicon oxide layer is formed by using slow deposition (Slow Depo), for example, the second silicon oxide layer is formed by a chemical vapor deposition apparatus having a power ranging from 300 W to 700 W, which thus slows down the material deposition rate to form a relatively compact film to enhance the blocking of oxygen and air.

In an exemplary embodiment, a film thickness of the second silicon oxide layer is about 800 to 1100 angstroms, the film thickness of the second silicon oxide layer is about a quarter of a film thickness of the first silicon oxide layer. Since a density of the second silicon oxide layer is different from a density of the first silicon oxide layer, the bonding force between two films is poor. When the flexible substrate is bonding, the thinner second silicon oxide layer is more flexible and thus avoids delamination from the first silicon oxide layer.

In the step S40, the amorphous silicon layer is formed on the surface of the second silicon oxide layer, a thickness of the amorphous silicon layer is equivalent to a thickness of the second silicon oxide layer, and the amorphous silicon layer is configured to enhancing the bonding force between the second polyimide layer and the second silicon oxide layer.

In a step S50 of forming a second polyimide layer on a surface of the amorphous silicon layer.

Referring to FIG. 2, according to the above object of the present invention, an embodiment according to present invention provides a flexible substrate manufactured by a manufacturing method of a flexible substrate of an OLED display panel, comprises: a first polyimide layer 201; a first silicon oxide layer 202 disposed on a surface of the first polyimide layer 201; a second silicon oxide layer 203 disposed on a surface of the first silicon oxide layer 202; an amorphous silicon layer 204 disposed on a surface of the second silicon oxide layer 203; and a second polyimide layer 205 disposed on a surface of the amorphous silicon layer 204.

The present invention has the advantages: in comparison with the prior art, the flexible substrate according to the present invention provides the manufacturing processes being relatively simplified such that the production efficiency of the flexible substrate is improved. In comparison with the film layers of the conventional flexible substrate, the present invention also can solve the technology problems as follows: since materials of the silicon oxide and silicon nitride are different, the manufacturing process needs to pass different material deposition apparatus, which results in the processes being more complicated and the efficiency of production being low.

In view of the above, although the present invention has been disclosed by way of preferred embodiments, the above preferred embodiments are not intended to limit the present invention, and one of ordinary skill in the art, without departing from the spirit and scope of the invention, the scope of protection of the present invention is defined by the scope of the claims.

What is claimed is:

1. A manufacturing method of a flexible substrate of an OLED display panel, comprising:
a step S10 of providing a first polyimide layer;
a step S20 of forming a first silicon oxide layer on a surface of the first polyimide layer;
a step S30 of forming a second silicon oxide layer on a surface of the first silicon oxide layer;
a step S40 of forming an amorphous silicon layer on a surface of the second silicon oxide layer; and
a step S50 of forming a second polyimide layer on a surface of the amorphous silicon layer;
wherein the step S10 further comprises:
a step S101 of forming a recess array on a side of the first polyimide layer which is away from the first silicon oxide layer.

2. The manufacturing method according to claim 1, wherein in the step S20 and the step S30, the first silicon oxide layer and the second silicon oxide layer are sequentially formed in a same chemical vapor deposition chamber, and wherein a material deposition time of the first silicon oxide layer is less than a material deposition time of the second silicon oxide layer.

3. The manufacturing method according to claim 2, wherein in the step S30, the second silicon oxide layer is deposited on the surface of the first oxide layer by using a chemical vapor deposition apparatus having a power ranging from 300 W to 700 W.

4. The manufacturing method according to claim 3, wherein a film thickness of the second silicon oxide layer is about 800 to 1100 angstroms.

5. The manufacturing method according to claim 4, wherein the film thickness of the second silicon oxide layer is about a quarter of a film thickness of the first silicon oxide layer.

6. A manufacturing method of a flexible substrate of an OLED display panel, comprising:
a step S10 of providing a first polyimide layer;
a step S20 of forming a first silicon oxide layer on a surface of the first polyimide layer;
a step S30 of forming a second silicon oxide layer on a surface of the first silicon oxide layer;
a step S40 of forming an amorphous silicon layer on a surface of the second silicon oxide layer; and
a step S50 of forming a second polyimide layer on a surface of the amorphous silicon layer.

7. The manufacturing method according to claim 6, wherein in the step S20 and the step S30, the first silicon oxide layer and the second silicon oxide layer are sequentially formed in the same chemical vapor deposition chamber, and wherein a material deposition time of the first silicon oxide layer is less than a material deposition time of the second silicon oxide layer.

8. The manufacturing method according to claim 7, wherein in the step S30, the second silicon oxide layer is deposited on the surface of the first oxide layer by using a chemical vapor deposition apparatus having a power ranging from 300 W to 700 W.

9. The manufacturing method according to claim 8, wherein a film thickness of the second silicon oxide layer is about 800 to 1100 angstroms.

10. The manufacturing method according to claim 9, wherein the film thickness of the second silicon oxide layer is about a quarter of a film thickness of the first silicon oxide layer.

11. A flexible substrate manufactured by the manufacturing method according to claim 6, comprising:
a first polyimide layer;
a first silicon oxide layer disposed on a surface of the first polyimide layer;
a second silicon oxide layer disposed on a surface of the first silicon oxide layer;
an amorphous silicon layer disposed on a surface of the second silicon oxide layer; and
a second polyimide layer disposed on a surface of the amorphous silicon layer.

12. The flexible substrate according to claim 11, wherein a film thickness of the second silicon oxide layer is about 800 to 1100 angstroms.

13. The flexible substrate according to claim 12, wherein the film thickness of the second silicon oxide layer is about a quarter of a film thickness of the first silicon oxide layer.

14. The flexible substrate according to claim 11, wherein a film consistency of the second silicon oxide layer is greater than a film consistency of the first silicon oxide layer

15. The flexible substrate according to claim 11, wherein a plurality of recesses arranged in an array arrangement are formed on a surface of the first polyimide layer and a surface of the second polyimide layer.
